(19) United States
(12) Patent Application Publication
(10) Pub. No.: US 2006/0013955 A1
(43) Pub. Date: Jan. 19, 2006

(54) Deposition of ruthenium and/or ruthenium oxide films

(76) Inventor: Yoshihide Senzaki, Austin, TX (US)

Correspondence Address: DORSEY & WHITNEY LLP, 555 CALIFORNIA STREET, SUITE 1000, SUITE 1000, SAN FRANCISCO, CA, 94104, US

(21) Appl. No.: 11/179,078

(22) Filed: Jul. 11, 2005

Related U.S. Application Data
(60) Provisional application No. 60/586,625, filed on Jul. 9, 2004.

(51) Int. Cl. C23C 16/00

(52) U.S. Cl. 427/248.1

(57) ABSTRACT

The present invention relates generally to methods for depositing ruthenium and/or ruthenium oxide films in the formation of semiconductor devices. More specifically, the present invention provides methods for deposition of ruthenium containing metal and metal-oxygen based films on the surface of a substrate.

### RELATED APPLICATIONS

This application claims the benefit of, and priority to, Unites States provisional patent application Ser. No. 60/586,625 filed on Jul. 9, 2004, the disclosure of which is incorporated by reference herein in its entirety.

### FIELD OF THE INVENTION

The present invention relates generally to methods for depositing ruthenium and/or ruthenium oxide films in the formation of semiconductor devices. More specifically, the present invention relates to a method for deposition of ruthenium containing metal-oxygen based films at low temperatures.

### BACKGROUND OF THE INVENTION

Advanced specifications for semiconductor devices require that the critical dimensions of such devices continue to shrink. These critical dimensions comprise the line widths and spacing of structures as well as the thickness of critical layers or films such as the diffusion barrier layers used in the interconnect scheme, the gate dielectric layer used in the active area of the transistor, and the thickness of the electrode materials used to form capacitor structures. In addition to the physical constraints placed on these films, new materials must also be developed and characterized to meet increasingly demanding performance specifications.

Currently accepted practices for the deposition of these materials used in the manufacture of semiconductor devices are by physical vapor deposition (PVD), chemical vapor deposition (CVD), atomic layer deposition (ALD), and the like. The physical mechanism of PVD yields poor step coverage (defined as the ratio of film thickness at the bottom or side wall of a via divided by the film thickness on a flat surface at the top of the via). The mechanism of CVD also yields deposited films with poor step coverage on high aspect ratio structures. Therefore, alternative methods are being explored for the deposition of layers for devices using 90 nm technology and below. ALD techniques are well suited to the deposition of a wide variety of both conductive and dielectric films used in the manufacture of a semiconductor device. ALD techniques have the advantage of depositing films with excellent step coverage as well as being a process that is used at lower temperatures than CVD.

In memory devices a capacitor structure is provided which generally employs a “silicon-insulator-silicon” (SIS) multilayer structure to form the capacitor. In this structure, a thin film of “doped” polysilicon is used as the electrode. Polysilicon is generally doped with various species such as boron, phosphorous, arsenic, and the like to lower the electrical resistance of the polysilicon layer. This is well known in the art. The capacitor dielectric material has traditionally been silicon dioxide or silicon nitride. The stringent requirements of advanced memory devices is leading to the replacement of these dielectric materials with metal oxides that have a higher permittivity. These are the “high-k” materials that are of such interest in the research and development field.

Memory device roadmaps are showing a trend away from the traditional SIS capacitor to more advanced device architectures. To enhance the performance of a device, a lower resistivity material such as a metal or conductive metal oxide is replacing the polysilicon electrode material. If only one of the electrodes is changed, the device architecture is known as a “metal-insulator-silicon” (MIS) structure. If both electrodes are changed, then the device architecture is known as a “metal-insulator-metal” (MIM) structure.

The metals or conductive metal oxides chosen to replace the polysilicon electrodes must meet a number of requirements. They must be chemically stable with respect to interaction with the surrounding materials over the temperatures encountered during the remainder of the device processing sequence. Some of the metals that might be considered for use as a capacitor electrode are not stable when placed in contact with the oxygen-containing dielectric material. The metal will then become oxidized at the interface and the resistivity of the electrode will rise to an unacceptable level.

Additionally, methods of fabrication must be considered and evaluated for suitability. For example, for advanced semiconductor device fabrication, liquid chemical precursors are in general preferred over solid chemical precursors for accurate chemical vapor delivery to the process chamber. Solid chemical precursors suffer from inconsistent surface area changes throughout the time of delivery. Additional requirements of the chemical precursors used in these alternative techniques include any one of high vapor pressure, low toxicity, good thermal stability, long shelf life, high purity, and low cost.

Accordingly, further development of fabrication techniques, particularly processes for fabricating capacitor films and structures is needed.

### BRIEF SUMMARY OF THE INVENTION

In general, the present invention provides a method for depositing a ruthenium containing metal or conductive metal oxide film or layer. Specifically, a method is provided to deposit ruthenium or ruthenium oxide at low temperatures on the surface of substrate or semiconductor device. The proper choice of the alkyl groups attached to the ruthenium atom in the chemical precursor retains the liquid state of the chemical precursors and allows control of the vapor pressure of the chemical precursor and reduction of the carbon contamination in the deposited metal-containing film.

In one aspect, the present invention provides a method of forming a ruthenium-containing film on the surface of a substrate, characterized in that: a first precursor containing at least one ruthenium atom is converted from a liquid state to a gaseous state. The gaseous state of said first precursor is conveyed to a process chamber and forms a monolayer on the surface of the substrate. Excess amounts of the first precursor are removed from the process chamber. At least one activated oxygen-containing reactant is conveyed to the process chamber and reacts with the monolayer of the first precursor to form a ruthenium-containing film. Excess amounts of the activated oxygen-containing reactant are removed from the process chamber.

In another aspect of the present invention, a method is provided for fabricating a ruthenium film in a process chamber characterized in that a ruthenium-containing precursor selected from any one or more of:
Ru(CpR)₂ where R is an alkyl group and Cp is cyclopentadiene,
Ru₃(CO)₁₂
Ru(CO)₄L, where L is (CF₃)CC(CF₃)
Ru(CO)₃(COD), where COD is cyclooctadiene
Ru(β-diketonate)₃, Ru(thd)₃ (where thd is tetramethylheptadionate)
Ru(OR)₃, where R is C1-C6 carbons
RuX₃, where X is a halogen atom such as Cl, F, Br, and I
Ru(RCp)(R′Cp), where R and R′ are H or C1-C6 carbons, or
Ru(RCp)R″, where R is H, or C1-C6 carbons, and R″ is C3-C10 carbons, is conveyed to the process chamber to form a monolayer on the surface of a substrate.

### BRIEF DESCRIPTION OF THE FIGURES

Other aspects, embodiments and advantages of the invention will become apparent upon reading of the detailed description of the invention and the appended claims provided below, and upon reference to the drawings in which:

FIG. 1 shows a simplified schematic drawing of an ALD system which may be employed to carry out embodiments of methods of the present invention; and

FIG. 2 is illustrates a simplified schematic drawing of another ALD system which may be employed to carry out alternative embodiments of methods of the present invention.

### DETAILED DESCRIPTION OF THE INVENTION

In general, embodiments of the present invention provide methods for forming ruthenium metal or ruthenium metal oxide films or layers on substrates. In some embodiments the methods are carried out at low temperatures using Atomic Layer Deposition (ALD).

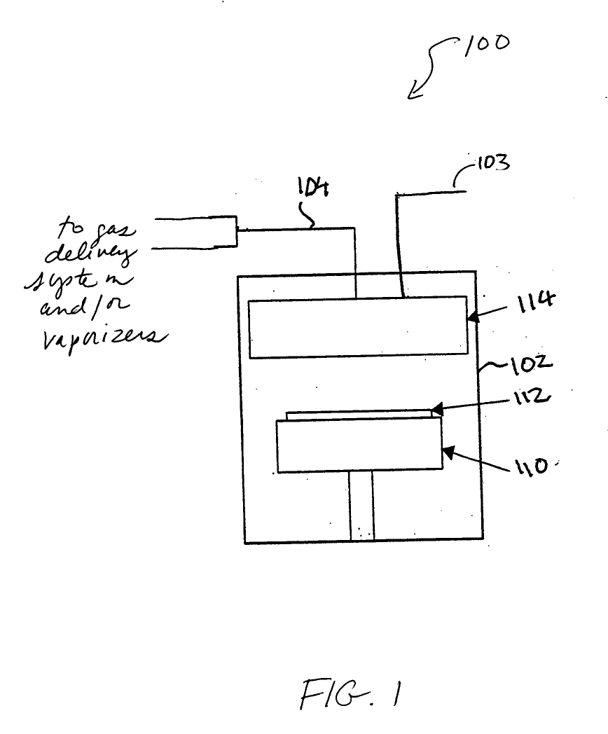

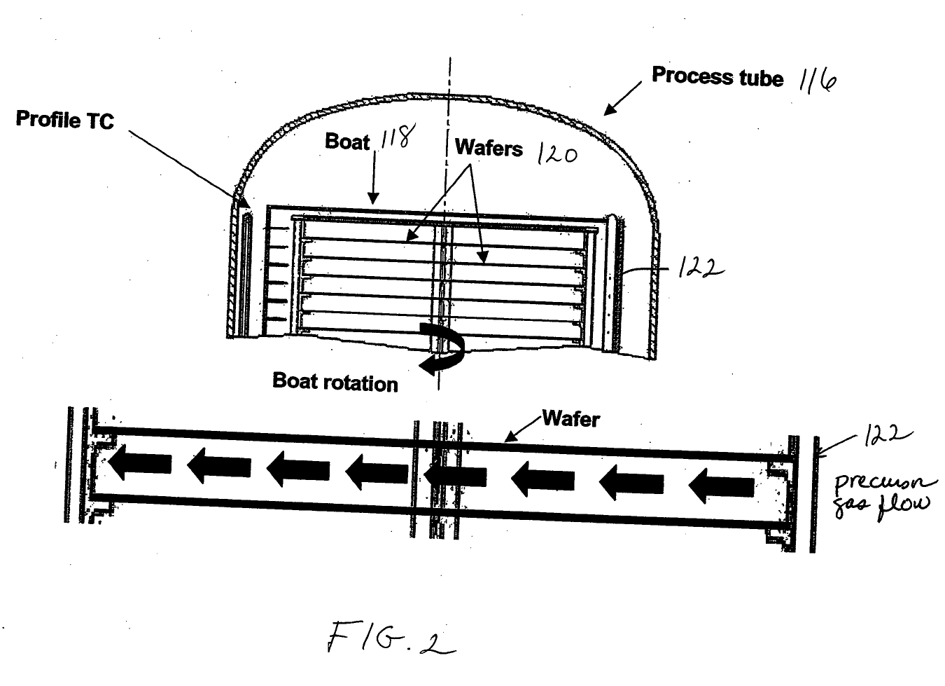

In one embodiment of the present invention, a substrate is placed in a process chamber and is heated to the desired temperature. The process chamber may be configured to hold a single substrate such as illustrated in FIG. 1, or may be configured to hold a plurality of substrates as shown in FIG. 2.

FIG. 1 is a simplified schematic diagram depicting one embodiment of a system for fabricating a films in accordance with one embodiment of the present invention. Referring to FIG. 1, in general the system 100 comprises a process chamber 102 which houses wafer support 110 for supporting a wafer or substrate 112. A gas inlet or injector 114 is provided for conveying deposition precursors and other gases 103 (for example, reactant gases such as oxidation gases and the like, or dilution gases) into the chamber 102 to form various layers or films on the surface of the substrate. In the illustrative embodiment, a gas manifold 104 interconnects one or more gas delivery systems and/or vaporizers (not shown) to the process chamber 102.

Alternatively, embodiments of the present invention may be employed with a batch processing chamber, or with a mini-batch chamber, such as generally illustrated in FIG. 2. In a batch or mini-batch chamber, generally comprises a process tube 116 which houses a wafer boat 118 supporting a plurality of wafers 120. A plurality of gas inlets or injectors 122 are used to convey the various gases, and the gases are typically conveyed over each substrate in a parallel or cross-flow manner. Examples of one embodiment of a mini-batch chamber are described in PCT patent application serial no. PCT/US03/21575 entitled Thermal Processing System and Configurable Vertical Chamber, the disclosure of which is incorporated by reference herein.

When a plurality of substrates are processed, both batch and mini-batch loads may be practiced with the present invention, and generally include a plurality of substrates between 1 and 200, 1 and 150, or 1 and 100 substrates. Smaller loads may also be employed, such as between 1 and 50 substrates, and 1 to 25 substrates. Examples of suitable substrates include, but are not limited to, silicon wafers, gallium arsenide wafers, glass substrates as used in the manufacture of flat panel displays, “thin film head” substrates as used to manufacture memory disk drives for computers, substrates used in the manufacture of photonic devices, substrates used in the manufacture of micro-electro-mechanical systems (MEMS) devices, polymeric substrates as might be used for organic-based devices, and the like.

According to some embodiments, to form the material on the substrate(s), a ruthenium-containing precursor is allowed to flow over one or more substrate(s) and saturate the surface forming a monolayer of the precursor. Excess amounts of the ruthenium-containing precursor are removed using known techniques such as inert gas purging, evacuation by a vacuum pump, or combinations thereof. An activated form of oxygen is then introduced to the chamber to react with the saturated monolayer of the precursor on the substrate(s). The flow, concentration, and exposure time of the activated form of oxygen are selected to result in the formation of a single layer of either pure metal or a conductive metal oxide on the substrates(s). The sequence is then repeated until the desired thickness of the ruthenium or ruthenium oxide is deposited on the substrate(s).

Ruthenium-containing precursors are employed. In some embodiments, the ruthenium-containing precursors are Ru(CpR)₂, where R is an alkyl group and Cp is cyclopentadiene. These “ruthenocene”-type precursors react with oxygen containing gases to form ruthenium metal. If the partial pressure of the oxygen species is increased, the reaction continues to form the conductive metal oxide, RuO₂. This is illustrated in the following equations (the equations are provided for illustration purposes only, and are not stoichiometrically balanced):
Ru(CpR)₂O→Ru, where R is H or an alkyl group
Ru+O→RuO₂
In some embodiments, the ALD process is performed at a temperature between 20° C. and 800° C., and more typically between 100° C. and 270° C. The process pressure is held between 0.001 mTorr and 600 Torr, and more typically between 10 mTorr and 5 Torr. The flow rates of the precursors, purge gases, and oxidation species are generally between 0 and 20,000 sccm, and more typically between 10 and 2000 sccm.

The Ru(CpR)₂ precursor is one example of a ruthenium compound that may be used as the ruthenium-containing precursor. Additional ruthenium compounds that may be used include, but are not limited to,
Ru₃(CO)₁₂
Ru(CO)₄L, where L is (CF₃)CC(CF₃)
Ru(CO)₃(COD), where COD is cyclooctadiene
Ru(β-diketonate)₃, Ru(thd)₃ (where thd is tetramethylheptadionate)
Ru(OR)₃, where R is C1-C6 carbons
RuX₃, where X is a halogen atom such as Cl, F, Br, and I
Ru(RCp)(R′Cp), where R and R′are H or C1-C6 carbons, and
Ru(RCp)R″, where R is H, or C1-C6 carbons, and R″ is C3 to C10 carbons.

The specific ruthenium compound used as the metal-containing precursor may be chosen by those skilled in the art with routine experimentation on the basis of the proposed chemistry used to deposit the film, final application for the deposited film, the architecture of the processing system, the economics of the process, and the desired properties of the deposited film. The proper choice of the alkyl groups attached to the center metal atom retains the liquid state of the chemical precursors and allows control of the vapor pressure of the chemical precursor and reduction of the carbon contamination in the deposited metal-containing film.

Once the monolayer containing ruthenium is formed on the surface of the substrate or film, oxygen-containing reactant gas is conveyed to the surface of the monolayer. used to supply the oxygen may take any number of forms. Oxygen-containing gases suitable for use may take any number of forms. In some embodiments, the oxygen-containing gas include individually or mixtures of O₂, H₂O, NO, N₂O, peroxides, air, and the like. In other embodiments, the oxygen-containing reactant is “activated” to further facilitate interaction of the oxygen reactant with the monolayer of ruthenium precursor that has been formed on the surface. In such embodiments, activation of the reactant promotes the ALD process and the ALD process is performed at low temperatures, in one example at temperatures lower than 270° C.

Activation of the oxygen-containing reactant may be accomplished by any number of suitable techniques such as direct plasma, remote plasma, RF frequency plasma, microwave frequency plasma, UV photon excitation, and the like. Activation may take place either inside the process chamber, or as part of the chemical delivery system external to the process chamber. Activation of the oxygen-containing reactant results in the formation of radical or energetic species which may include, but are not limited to, O₃, atomic oxygen, excited species of O, OH, NO, and the like.

The foregoing description of specific embodiments of the invention has been presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and

What is claimed is:

1. A method of forming a ruthenium-containing film on the surface of a substrate, characterized in that:
a first precursor containing at least one ruthenium atom is converted from a liquid state to a gaseous state;
said gaseous state of said first precursor is conveyed to a process chamber and forms a monolayer on the surface of the substrate;
excess amounts of the first precursor are removed from the process chamber;
at least one oxygen-containing reactant is conveyed to the process chamber and reacts with the monolayer of the first precursor to form a ruthenium metal-containing material; and
excess amounts of the activated oxygen-containing reactant are removed from the process chamber.

2. The method of claim 1 wherein, the substrate surface is selected from semiconductor materials, compound semiconductor materials, silicon, plastics, polymers, metals, alloys, organics, inorganics, and mixtures thereof.

3. The method of claim 1 wherein the first precursor is selected from any one or more of:
Ru₃(CO)₁₂
Ru(CO)₄L, where L is (CF₃)CC(CF₃)
Ru(CO)₃(COD), where COD is cyclooctadiene
Ru(β-diketonate)₃, Ru(thd)₃, (where thd is tetramethylheptadionate)
Ru(OR)₃, where R is C1-C6 carbons
RuX₃, where X is a halogen atom such as Cl, F, Br, and I
Ru(RCp)(R′Cp), where R and R′ are H or C1-C6 carbons
Ru(RCp)R″, where R is H, or C1-C6 carbons, and R″ is C3 to C10 carbons, and mixtures thereof.

4. The method of claim 1, wherein said oxygen-containing reactant is selected from any one or more of:
oxygen, water, peroxides, air, nitrous oxide, nitric oxide, H₂O₂, and mixtures thereof.

5. The method of claim 1, wherein the oxygen-containing reactant activated, and is selected from any one or more of:
ozone, singlet oxygen, triplet oxygen, atomic oxygen, excited species of O, OH, NO, and mixtures thereof.

6. The method of claim 1, wherein the partial pressure of the oxygen-containing reactant is selected to result in the deposition of a ruthenium film on the surface of the substrate.

7. The method of claim 1, wherein the partial pressure of the oxygen-containing reactant is selected to result in the deposition of a conductive ruthenium oxide film on the surface of the substrate.

8. The method of claim 1, wherein said film forming method is carried out at a temperature in the range of approximately 20 to 800° C.

9. The method of claim 1, wherein said film forming method is carried out at a temperature in the range of approximately 20 to 270° C.

10. The method of claim 1, wherein said process chamber is at a pressure in the range of approximately 0.001 mTorr to 600 Torr.

11. The method of claim 1, wherein said process chamber is at a pressure in the range of approximately 10 mTorr to 5 Torr.

12. The method of claim 1, wherein the total gas flow rate to the process chamber comprising the conveying of the first precursor, the oxygen-containing reactant, and additional purge gases during any single step is in the range of approximately 0 to 20,000 sccm.

13. The method of claim 1, wherein said process chamber is configured to house a single substrate.

14. The method of claim 1, wherein said process chamber is configured to house a plurality of substrates.

15. The method of claim 14, wherein the plurality of substrates numbers between 1 and 200.

16. The method of claim 14, wherein the plurality of substrates numbers between 1 and 150.

17. The method of claim 14, wherein the plurality of substrates numbers between 1 and 100.

18. The method of claim 14, wherein the plurality of substrates numbers between 1 and 50.

19. The method of claim 14, wherein the plurality of substrates numbers between 1 and 25.

20. The method of claim 1 wherein the first precursors is of the formula Ru(CpR)₂, where R is an alkyl group and Cp is cyclopentadiene.

21. A method of forming a ruthenium-containing film on the surface of a substrate, characterized in that one or more ruthenium-containing precursors selected from any one or more of: Ru(CpR)₂, where R is an alkyl group and Cp is cyclopentadiene Ru₃(CO)₁₂; Ru(CO)₄L, where L is (CF₃)CC(CF₃); Ru(CO)₃(COD), where COD is cyclooctadiene; Ru(β-diketonate)₃; Ru(thd)₃, (where thd is tetramethylheptadionate); Ru(OR)₃, where R is C1-C6 carbons; RuX₃, where X is a halogen atom such as Cl, F, Br, and I; Ru(RCp)(R′Cp), where R and R′ are H or C1-C6 carbons; Ru(RCp)R″, where R is H, or C1-C6 carbons, and R″ is C3 to C10 carbons, and mixtures thereof,
are conveyed to a process chamber in a vaporous state to form a monolayer of the ruthenium-containing precursor on the surface of one or more substrates, and subsequently one or more oxygen-containing precursors are conveyed to the process chamber and interact with the monolayer to form a ruthenium metal or ruthenium metal oxide layer on the substrate.
